(19) United States
(12) Patent Application Publication
(10) Pub. No.: US 2002/0088634 A1
(43) Pub. Date: Jul. 11, 2002

(54) QFN package and a fabrication method thereof

(76) Inventors: Shu-Chiu Chiu, Taichung (TW); Kun-Ming Huang, Changhua (TW); Ching-Kun Yeh, Taichung (TW)

Correspondence Address: J.C. Patents, Inc., Suite 114, 1340 Reynolds Ave., Irvine, CA, 92614, US

(21) Appl. No.: 09/927,724

(22) Filed: Aug. 10, 2001

(30) Foreign Application Priority Data
Jan. 5, 2001 (TW) 90100250

(51) Int. Cl. H01L 23/28

(52) U.S. Cl. 174/52.2

(57) ABSTRACT

A QFN package comprising a die pad, which has a first upper surface and a corresponding first lower surface, and at least a loop shaped groove conformal to, and inside the periphery of, the first lower surface of the die pad. A plurality of leads are formed and located along the boundary edges of the die pad. Each lead has a second upper surface and a corresponding second lower surface. A chip has an active surface and a corresponding back surface, and its back surface is adhered on the first upper surface of the die pad. A plurality of bonding pads is formed on the active surface of the chip, and are electrically connected to the leads. A molding compound, which encapsulates the chip, the die pad and the leads, leaves exposed on the first lower surface of the die pad and the second lower surfaces of the leads.

### CROSS-REFERENCE TO RELATED APPLICATION

This application claims the priority benefit of Taiwan application serial no. 90100250, filed Jan. 5, 2001.

### BACKGROUND OF THE INVENTION

1. Field of Invention

The present invention relates generally to a quad flat non-leaded (QFN) package and a fabrication method thereof. More particularly, the present invention relates to an improved QFN package reducing a flash problem and its fabrication method.

2. Description of the Related Art

As the demand for smaller electronic products increases, electronics industries must continuously develop higher-density electronic packaging. Various techniques have been developed to meet the demands for higher quality and improved reliability, and various chip scale package (CSP) techniques have been developed for high-density packages.

The QFN package is one of these CSP techniques, based on a lead frame and used for low pin count devices. The main characteristic of the QFN package is that it consists of no external leads, thus shortening the transmitting distance and reducing resistance to improve signal transmission.

FIG. 1 illustrates a diagrammatic view of a conventional QFN package structure. FIG. 1A is a diagrammatic bottom view of FIG. 1. The conventional QFN package structure 100 comprises: a chip 110, a die pad 132, a plurality of leads 138 and a molding compound 150. The chip 110 has an active surface 112 and a corresponding back surface 114. A plurality of bonding pads 116 is formed on the active surface 112 of the chip 110. The die pad 132 has an upper surface 134 and a lower surface 136, and each lead 138 has an upper surface 140 and a lower surface 142. The back surface 114 of the chip 110 is adhered onto the upper surface 134 of the die pad 132. A plurality of conductive wires 144 electrically connect the bonding pads 116 to the leads 138. A molding compound 150 encapsulates the chip 110, the conductive wires 144, the upper surface 134 of the die pad 132 and the upper surfaces 140 of the leads 138. Ideally the lower surface 136 of the die pad 132 and the lower surfaces 142 of the leads 138 should be left completely exposed for further connections.

The conventional method of fabricating a QFN package is first to adhere a tape (not shown) onto the lower surfaces 142 of the leads 138 and the lower surface 136 of the die pad 132. The tape is supported by a support body (not shown). Following this, the chip 110 is adhered onto the upper surface 134 of the die pad 132, and the back surface 114 of the chip 110 comes into contact with the upper surface 134 of the die pad 132. A wire bonding process is carried out to electrically connect the bonding pads 116 to the leads 138 by conductive wires 144. A molding process is carried out and finally the tape is removed, and a trimming process is carried out.

FIG. 1A and FIG. 2are diagrammatic views illustrating a step of a molding process of a QFN package by a conventional method. A molding compound 150 is quickly filled into a cavity 154 of a molding 152, but because the molding compound 150 has a high temperature, a detaching problem between the tape 160 and the lower surface 136 of the die pad 132 will occur easily. Thus a gap 170 will form between the tape 160 and the lower surface 136 of the die pad 132. The molding compound 150 can fill into the gap 170 to form a molding flash 180. An extra polishing process step is needed to remove the molding flash 180 from the surface, and thus the cost of the production is increased and production line efficiency is reduced.

### SUMMARY OF THE INVENTION

It is an object of the present invention to provide a QFN package and a method that can simplify the fabricating process and reduce the cost.

It is another object of the present invention to provide a QFN package and a method to prevent the molding flash from occurring and reduce the affected area.

To achieve the foregoing and other objects and in accordance with the purpose of the present invention, the present invention provides a QFN package, which comprises: a die pad, which has a first upper surface, a corresponding first lower surface and at least a loop shaped groove. The loop shaped groove is conformal to, and inside the periphery of, the first lower surface of the die pad. A plurality of leads are located around the boundary edges of the die pad, and each lead has a second upper surface and a corresponding second lower surface. A chip has an active surface and a corresponding back surface. The back surface of the chip is adhered onto the first upper surface of the die pad. A plurality of bonding pads that is formed on the active surface of the chip and the bonding pads is electrically connected to the leads. A molding compound encapsulates the chip, the die pad and leads, and the first lower surface of the die pad and the second lower surface of the leads are exposed.

The present invention further provides a lead frame, utilized in a QFN package, which comprises: a die pad, which has a first upper surface, a corresponding first lower surface and at least a loop shaped groove. The loop shaped groove is conformal to, and inside the periphery of, the first lower surface of the die pad. A plurality of leads is located around the boundary edges of the die pad, and each lead has a second upper surface and a corresponding second lower surface.

The present invention further provides a method of fabricating a QFN package, comprising: providing a lead frame, which comprises at least a package unit. The package unit comprises a die pad and a plurality of leads. The die pad has a first upper surface, a corresponding first lower surface and a loop shaped groove. The loop shaped groove is conformal to, and inside the periphery of, the first lower surface of the die pad, and the leads are located around the boundary edges of the die pad. Each lead has a second upper surface and a corresponding second lower surface. A tape is adhered onto the first lower surface of the die pad and the second lower surface of the leads. A chip has an active surface and a corresponding back surface, and a plurality of bonding pads are formed on the active surface of the chip. The back surface of the chip is adhered onto the first upper surface of the die pad. The bonding pads are connected electrically to the leads. A molding process is performed, wherein a molding compound encapsulates the chip, the first upper surface of the die pad and the second upper surface of the leads. The tape will be deformed to form a bump inside the empty space of the loop shaped groove due to the high temperature and pressure. The deformed tape and the loop shaped groove prevent the molding compound from forming between the tape and the first lower surface of the die pad. The tape is removed afterward and a process is carried out to separate out each packaging unit.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIG. 1 is a diagrammatic view of a structure of a QFN package by a conventional method;

FIG. 1A is a bottom view of FIG. 1;

FIG. 2 is a diagrammatic view illustrating a molding step of a QFN package by a conventional method;

FIGS. 3-6 are diagrammatic views illustrating steps of a fabrication method of a QFN package in accordance with a preferred embodiment of the present invention;

FIG. 3A is a diagrammatic bottom view of the die pad shown in FIG. 3;

FIG. 3B is a diagrammatic top view of the lead frame shown in FIG. 3;

FIG. 4A is a diagrammatic magnified view of a portion of region 400 on FIG. 4.

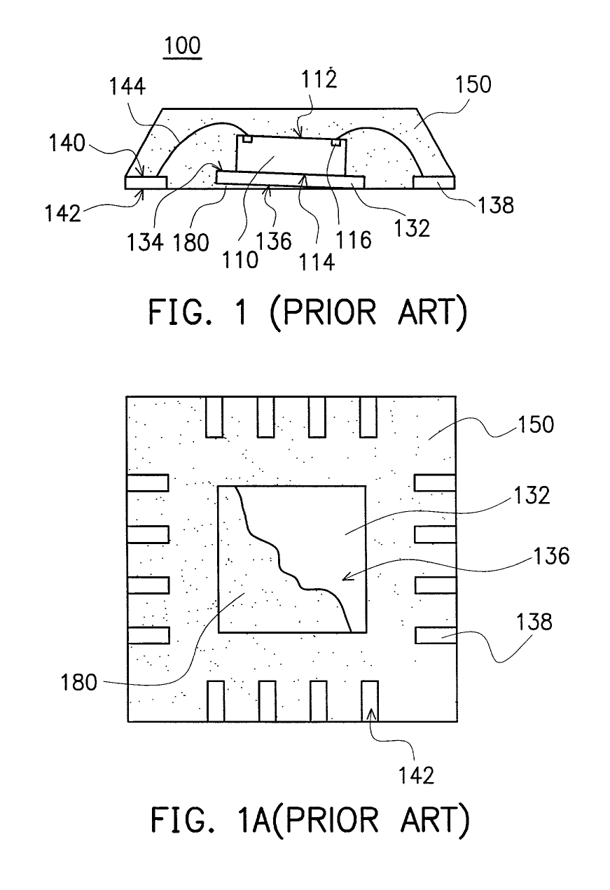

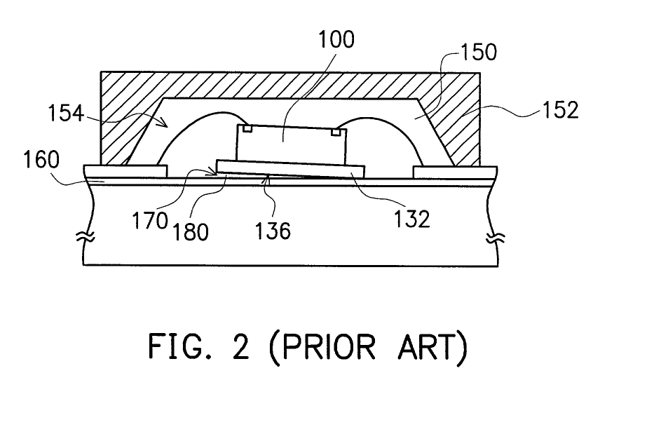

### DESCRIPTION OF THE PREFERRED EMBODIMENTS

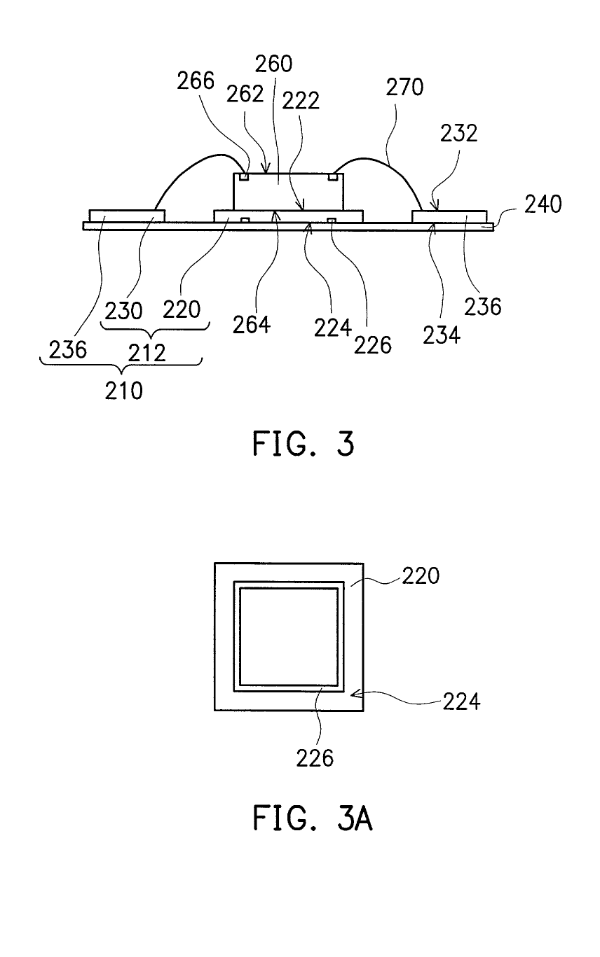

FIGS. 3-6 are diagrammatic views illustrating steps of a method of fabricating a QFN package in accordance with a preferred embodiment of the present invention.

Referring to FIG. 3, FIG. 3A and FIG. 3B, FIG. 3A is a bottom view of the die pad shown in FIG. 3, and FIG. 3B is a top view of the lead frame shown in FIG. 3.

FIG. 3B illustrates a lead frame 210 that is provided. A plurality of package units 212 and dam bars 236 are formed on the lead frame 210. The dam bars 236 are located around the peripheral sides of each package unit 212, which comprises a die pad 220, a plurality of leads 230 and a plurality of support bars 239. The leads 230 are located around the peripheral sides of each die pad 220, but the leads 230 do not come into contact with the die pad 220. Each lead 230 is connected to the dam bar 236, and the support bars 239 connect the die pads 220 to the dam bars 236.

FIG. 3 illustrates the die pad 220, which comprises a first upper surface 222, a corresponding first lower surface 224 and a loop shaped groove 226 (shown on FIG. 3A). The loop shaped groove is conformal to, and inside the periphery of, the first lower surface 224 of the die pads 220. The leads 230 are located along the boundary edges of each die pad 220, and each lead 230 has a second upper surface 232 and a corresponding second lower surface 234.

The first lower surface 224 of the die pad 220 and the second lower surface 234 of the lead 230 are both adhered to a tape 240. A chip 260is provided, which has an active surface 262 and a corresponding back surface 264. A plurality of bonding pads 266 is formed on the active surface 262 of the chip 260, and the back surface 264 of the chip 260 is adhered to the first upper surface 222 of the die pad 220. A wire bonding process is carried out to electrically connect the bonding pads 266 to the leads 230 through a plurality of conductive wires 270.

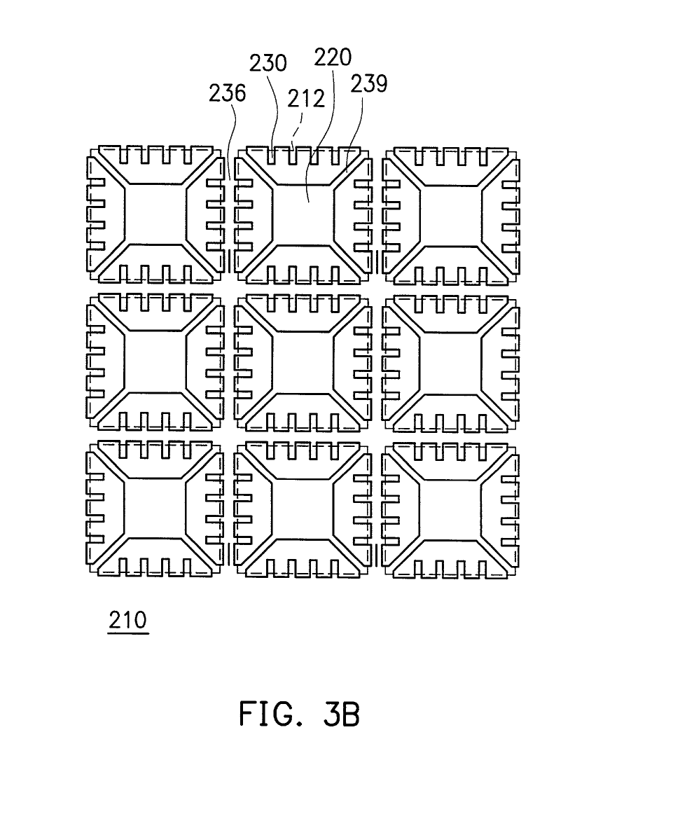

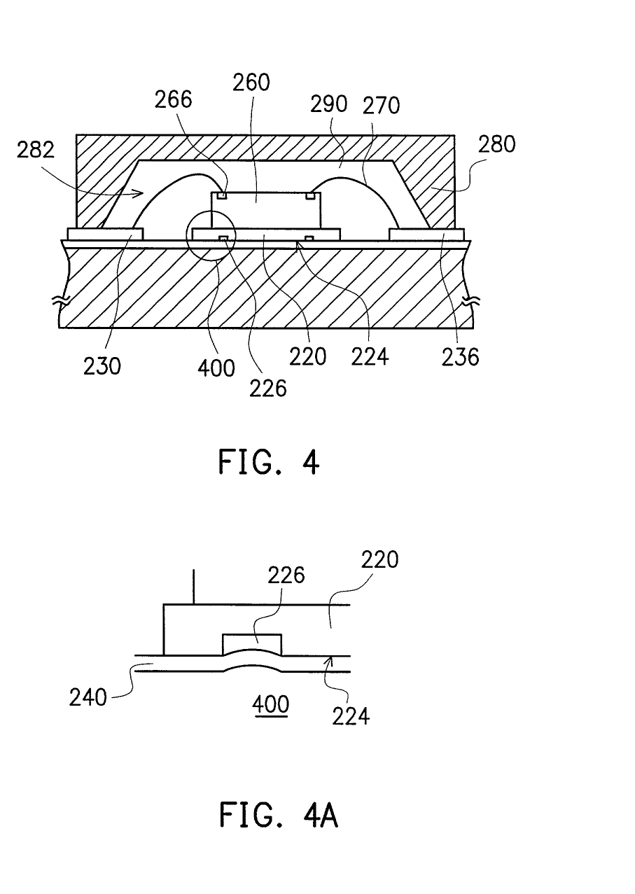

Referring to FIG. 4, a molding process is carried out. A mold 280 has an upper mold and a lower mold in which a cavity 282 is formed on the upper mold. The cavity 282 is located over the chip 260, conductive wires 270, die pads 220 and leads 230. A molding compound 290 is filled into the cavity 282, the molding compound 290 is allowed to cure, and the mold 280 is removed. The structure shown in FIG. 5 is obtained.

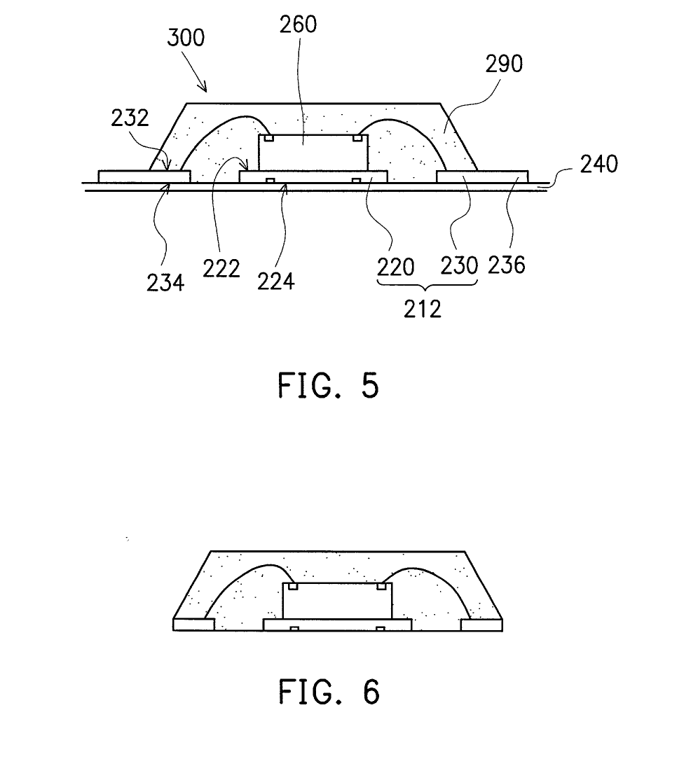

Referring to FIG. 5, the molding compound 290 encapsulates the chip 260, the first upper surface 222 of the die pad 220, the second upper surface 232 of the lead 230 and the first lower surface 224 of the die pad 220 and the second lower surface 234 of the leads 230 are exposed. The tape 240 is removed from the lead frame, and a punch method or a sawing method is used to separate the dam bars 236 from the leads 230. The package units 212 are thus separated from each other. The structure shown in FIG. 6 is obtained.

Referring to FIG. 4 and FIG. 4A, FIG. 4A is a magnified view of a portion of a region 400 on FIG. 4. The loop shaped groove 226 is located at the first lower surface 224 of the die pad 220. When the melting molding compound is filled into the cavity 282 of the mold 280, the temperature and pressure inside the cavity 282 rise fast, causing the tape 240 to heat up and deform. Due to the heat, the deformed tape 240 stretches into the empty space of the loop shaped groove 226. This condition causes the tape 240 to adhere tightly onto the first lower surface 224 of the die pad 220. Thus the detaching problem between the die pad 220 and the tape 240 is prevented. The molding flash problem on the die pad 220 is also prevented. The step of the conventional method of cleaning the molding flash that formed on the die pad 220 can be omitted, thus the present invention simplifies the fabricating process. If the molding flash does occur, the affected area will only be on the outer region of the groove 226, the inner area of the loop shaped groove will not be affected. Thus the area affected by the molding flash is reduced.

In view of the above, the present invention includes the advantages of:

1. Providing an improved QFN package and the fabrication method thereof. The QFN package has a loop shaped groove, which can prevent the molding flash problem. When the molding compound is filled into the cavity of the molding, the temperature and pressure inside the cavity rises fast, causing the tape to heat up and deform. The deformed tape stretches into the empty space of the loop shaped groove, and due to the stretching, the tape adheres more tightly onto the first lower surface of the die pad, thus preventing the detaching problem between the die pad and the tape. A molding flash problem on the die pad is also prevented.

2. The improved QFN package and fabrication method of the present invention further provides a method which reduces the affected area on the die pad, when the molding flash does occur. The loop shaped groove can prevent the molding compound from forming between the tape and the first lower surface of the die pad, it can only spread to the outer region of the loop shaped groove, thus the inner area of the groove and the die pad will not be affected.

Other embodiments of the invention will appear to those skilled in the art from consideration of the specification and practice of the invention disclosed herein. It is intended that the specification and examples are to be considered as exemplary only, with a true scope and spirit of the invention being indicated by the following claims.

What is claimed is:

1. A QFN package comprising:
a die pad having a first upper surface and a first lower surface, wherein a loop shaped groove is conformal to, and inside the periphery of, the first lower surface;
a plurality of leads located around the boundary edges of the die pad, wherein each lead has a second upper surface and a second lower surface;
a chip having an active surface and a corresponding back surface, wherein the back surface of the chip is adhered onto the first upper surface of the die pad, and a plurality of bonding pads, which are formed on the active surface, are electrically connected to the leads; and
a molding compound encapsulating the chip, the die pad and leads, wherein the first lower surface of the die pad and the second lower surfaces of the leads are exposed.

2. The QFN package of claim 1, wherein the bonding pads are electrically connected to the leads by a plurality of conductive wires.

3. A lead frame comprising:
a die pad having a first upper surface, a corresponding first lower surface, wherein at least a loop shaped groove, is conformal to, and inside the periphery of, the first lower surface; and
a plurality of leads located around the boundary edges of the die pad, wherein each lead has a second upper surface and a second lower surface.

4. A method of fabricating a QFN package, the steps of the method comprising:
providing a lead frame, which comprises at least a package unit, each package unit comprising: a die pad having a first upper surface, a corresponding first lower surface and at least a loop shaped groove conformal to, and inside the periphery of, the first lower surface, and a plurality of leads located around the boundary edges of the die pad, wherein each lead has a second upper surface and a corresponding second lower surface;
adhering a tape onto the first lower surface of the die pad and the second lower surfaces of the leads;
providing a chip, which has an active surface and a corresponding back surface, wherein a plurality of bonding pads are formed on the active surface;
adhering the back surface of the chip onto the first upper surface of the die pad;
connecting electrically the bonding pads to the leads;
performing a molding process by using a molding compound to encapsulate the chip, the first upper surface of the die pad and the second upper surfaces of the leads, wherein the tape on the first lower surface of the die pad is stretched into an empty space of the loop shaped groove to leave the tape adhered tightly onto the die pad for preventing the molding compound from forming between the first lower surface of the die pad and the tape; and
removing the tape, and performing a process to separate the package units from each other.

5. The method of claim 4, wherein the bonding pads are electrically connected to the leads by a plurality of conductive wires utilizing a wire bonding method.

6. The method of claim 4, wherein the step of removing the tape causes the molding compound to leave exposed on the first lower surface of the die pad and the second lower surfaces of the leads.
